(19) United States
(12) Patent Application Publication
(10) Pub. No.: US 2022/0058897 A1
(43) Pub. Date: Feb. 24, 2022

(54) VEHICLE INSPECTION DEVICE AND ARTICLE TRANSFER SYSTEM HAVING THE SAME

(71) Applicant: SEMES CO., LTD., Cheonan-si (KR)

(72) Inventors: Tae In KIM, Pyeongtaek-si (KR); Jong Seon JOEN, Hwaseong-si (KR); Hyun Seong MOON, Hwaseong-si (KR); Shin Young CHEONG, Suwon-si (KR)

(73) Assignee: SEMES CO., LTD., Cheonan-si (KR)

(21) Appl. No.: 17/406,641

(22) Filed: Aug. 19, 2021

(30) Foreign Application Priority Data
Aug. 19, 2020 (KR) 10-2020-0103795

(51) Int. Cl. G07C 5/10; G07C 5/00; B66F 9/06; B66F 17/00

(52) U.S. Cl. CPC G07C 5/10; B66F 17/00; B66F 9/06; G07C 5/008

(57) ABSTRACT

A vehicle inspection device includes a storing part and a diagnosing part. The storing part is configured to store operation information in response to operations of vehicles to transport and load/unload an article along a transfer path. The diagnosing part is configured to compare the operation information stored in the storing part with a reference operation information of a vehicle to diagnose symptom of abnormality in the vehicles.

### CROSS-REFERENCE TO RELATED APPLICATION

This application claims priority to Korean Patent Application No. 10-2020-0103795, filed on Aug. 19, 2020 and all the benefits accruing therefrom under 35 U.S.C. § 119, the contents of which are incorporated by reference in their entirety.

### TECHNICAL FIELD

The present disclosure relates to a vehicle inspection device and an article transfer system having the same. More particularly, the present disclosure relates to a vehicle inspection device which transports an article through a transfer path, and an article transfer system having the same.

### BACKGROUND

Generally, an overhead hoist transport device transports an article by driving a plurality of vehicles along a driving rail. Also, the vehicles load or unload the article to a load port.

The vehicles repeatedly operate driving operation and the load/unload operation, and information of the driving operation and the load/unload operation may be sensed by a sensor prepared in the vehicles.

When a value sensed by the sensor is out of a predetermined reference, the vehicle is determined to be abnormal.

When the vehicle is abnormal, the operation of the overhead hoist transport device is stopped, and the vehicle is transported to a separate place and cause of the abnormality in the vehicle is inspected.

Since time is required to check the abnormality of the vehicle and to transport the abnormal vehicle to the separate place, the time of stopping the operation of the overhead hoist transport device may be increased. Thus, efficiency of the overhead hoist transport device may be decreased.

### SUMMARY

The example embodiments of the present invention provides a vehicle inspection device capable of inspecting abnormality in a vehicle and an article transfer system having the same.

According to one exemplary embodiment of the present invention, a vehicle inspection device includes a storing part and a diagnosing part. The storing part is configured to store operation information in response to operations of vehicles to transport and load/unload an article along a transfer path. The diagnosing part is configured to compare the operation information stored in the storing part with a reference operation information of a vehicle, which is previously stored, to diagnose symptom of abnormality in the vehicles.

In one exemplary embodiment, the diagnosing part may receive the operation information from the storing part based on position of the vehicles in the transfer path.

In one exemplary embodiment, the diagnosing part may receive the operation information from the storing part by each of the vehicles.

In one exemplary embodiment, the vehicle inspection device may further include an analyzing part configured to analyze cause of the abnormality in the vehicles using position of the vehicles and history information of occurrence of the abnormality in the vehicles, the analyzing part analyzing whether the cause of the abnormality in the vehicles is the vehicles itself or is from external environment including the transfer path, when the diagnosing part diagnoses the symptom of the abnormality.

In one exemplary embodiment, the storing part may store the operation information in real time.

In one exemplary embodiment, the storing part may store the operation information in a constant period.

In one exemplary embodiment, the operation information may be acquired by sensors prepared on the vehicles, and the operation information may include information of transport operation and information of load/unload operation of the vehicles.

In one exemplary embodiment, the operation information may be acquired by sensors prepared on the vehicles, and the operation information may include at least one of operation information and digital input/output information of motors prepared on the vehicles.

In one exemplary embodiment, the operation information may be acquired by sensors prepared on the vehicles, and the operation information may include at least one of time information, distance information, distribution information, and control sequence information of unit operation of the vehicles.

In one exemplary embodiment, the storing part may be prepared on each of the vehicles, and the storing part may exchange the information with the diagnosing part through wireless communication.

In one exemplary embodiment, the storing part may be prepared to be separated from the vehicles, and the vehicles may exchange the information with the storing part through wireless communication.

According to one exemplary embodiment of the present invention, a vehicle inspection device includes a storing part and a diagnosing part. The storing part is configured to store position information of each of a plurality of vehicles and operation information of the vehicles at each position with respect to the vehicles configured to transport and load/unload an article along a transport path. The diagnosing part is configured to compare the position information of the vehicles, which is stored in the storing part, with a previously stored reference operation information, and to diagnose symptom of abnormality of the vehicles.

In one exemplary embodiment, the vehicle inspection device may further include an analyzing part configured to analyze position of the vehicles and history information of occurrence of the abnormality in the vehicles to determine whether cause of the abnormality in the vehicles is the vehicles itself or is from external environment including the transfer path, when the diagnosing part diagnoses the symptom of the abnormality.

According to one exemplary embodiment of the present invention, an article transfer system includes a transfer path, a plurality of vehicles, a plurality of sensors, a storing part, and a diagnosing part. The vehicles are configured to transfer and load/unload an article along the transfer path. The sensors are prepared on each of the vehicles and configured to sense operation information of the vehicles. The storing part is configured to store operation information of the vehicles, which is transmitted from the sensors. The diagnosing part is configured to compare the operation information stored in the storing part with a reference operation information of a vehicle, which is previously stored, to diagnose symptom of abnormality of the vehicles.

In one exemplary embodiment, the diagnosing part may receive the operation information from the storing part based on position of the transfer path.

In one exemplary embodiment, the diagnosing part may receive the operation information from the storing part by each of the vehicles.

In one exemplary embodiment, the article transfer system may further include an analyzing part configured to analyze whether cause of the abnormality in the vehicles is the vehicles itself or is from external environment including the transfer path using position of the vehicles and history information of occurrence of the abnormality in the vehicles, when the diagnosing part diagnoses the symptom of the abnormality.

In one exemplary embodiment, the article transfer system may further include a position checking unit including a position display part prepared on the transfer path to check position of the vehicles on the transfer path, and a recognizing part prepared on the vehicles to recognize the position display part.

In one exemplary embodiment, the article transfer system may further include a position checking unit including a global position system (GPS) receiver prepared on each of the vehicles to check position of the vehicles on the transfer path.

In one exemplary embodiment, the article comprises a storage container configured to store a good.

According to the present invention, the vehicle inspection device analyzes the operation information of the vehicles, and may diagnose symptom of abnormality in the vehicles. Therefore, the vehicles having the symptom of the abnormality are preventively maintained, and the abnormality of the vehicles may be decreased. Since the stoppage of the vehicle transport system caused by the abnormality of the vehicles is decreased, the efficiency of the vehicle transport system may be improved.

Also, in the vehicle inspection device, when the diagnosing part diagnoses the symptom of the abnormality, the analyzing part analyzes the position of the vehicles and the history information of occurrence of the abnormality in the vehicles, and may analyze the cause of the abnormality in the vehicles whether the abnormality is caused by the vehicle itself or caused by external environment out of the vehicles. Therefore, the cause of the abnormality may be rapidly diagnosed and resolved.

### BRIEF DESCRIPTION OF THE DRAWINGS

Exemplary embodiments can be understood in more detail from the following description taken in conjunction with the accompanying drawings, in which:

FIG. 1 is a structural view illustrating an article transport system according one exemplary embodiment of the present invention;

FIG. 2 is a side view illustrating a position checking unit shown in FIG. 1 according to another exemplary embodiment of the present invention; and

FIG. 3 is a structural view illustrating a vehicle inspection device shown in FIG. 1 according to another exemplary embodiment of the present invention.

### DETAILED DESCRIPTION OF EMBODIMENTS

Hereinafter, a charge collecting plate for a fuel cell and a stack structure having the same according to embodiments of the present invention will be described in detail with reference to enclosed drawings. It is important to understand that the present invention may be embodied in many alternative forms and should not be construed as limited to the example embodiments set forth herein. While the invention is susceptible to various modifications and alternative forms, specific embodiments thereof are shown by way of example in the drawings and will herein be described in detail. It should be understood, however, that there is no intent to limit the invention to the particular forms disclosed, but on the contrary, the invention is to cover all modifications, equivalents, and alternatives falling within the spirit and scope of the invention. In describing each drawing, like numerals are used for like elements. In the enclosed drawings, the sizes and relative sizes of layers and regions may be exaggerated for clarity. Like numerals refer to like elements throughout.

It will be understood that, although the terms first, second, etc. may be used herein to describe various elements, these elements should not be limited by these terms. These terms are used to distinguish one element from another. For example, a first element discussed below could be termed a second element without departing from the teachings of the present inventive concept. Also, a second element discussed below could be termed a first element without departing from the teachings of the present inventive concept.

The terms used in the present invention is only used to describe particular embodiments, and it is not intended to limit the present invention. As used herein, the singular forms “a,” “an,” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

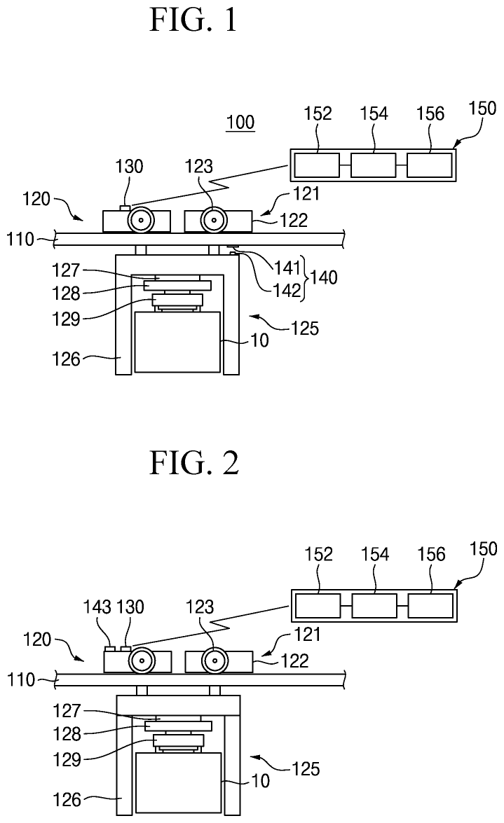

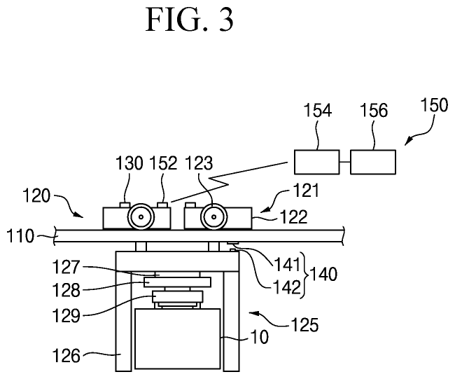

FIG. 1 is a structural view illustrating an article transport system according one exemplary embodiment of the present invention. FIG. 2 is a side view illustrating a position checking unit shown in FIG. 1 according to another exemplary embodiment of the present invention. FIG. 3 is a structural view illustrating a vehicle inspection device shown in FIG. 1 according to another exemplary embodiment of the present invention.

Referring to FIGS. 1 to 3, the article transport system 100 is configured to transport and load/unload an article 10, and the article 10 may be a storage container configured to store goods. Examples of the articles 10 may include a cassette, a front opening unified pod (FOUP), a front opening shipping box (FOSB), a magazine, a tray, etc. Examples of the goods may include a semiconductor device, a printed circuit board, a reticle, etc.

The article transport system 100 may include a transfer path 110, a plurality of vehicles 120, a sensor 130, a position checking unit 140, and a vehicle inspection device 150.

The transport path 110 is a path configured to transport an article 10, and the transport path 110 may be formed along a plurality of process devices (not shown) configured to perform processes for the good.

The transport path 110 may include a straight path, a curved path, an inclined path, branched/joined paths, etc.

The transport path 110 may include a driving rail.

The vehicles 120 may load and unload the articles 10 along the transport path 110.

Each of the vehicles 120 may include a transport unit 121 and a load/unload unit 125.

The transport unit 121 moves along the transport path 110.

A pair of the transport units 121 may be prepared, and may be lineally arranged along a driving direction of the vehicles 120. The transport unit 121 may include a body 122 and a plurality of driving wheels 123. The body 122 has a substantially hexahedral shape. The body 122 is connected to the load/unload unit 125. Here, the body 122 may rotate about an up and down direction of the load/unload unit 125 as a central axis.

Although not shown in figures, a motor (not shown) configured to rotate the driving wheels 123 may be prepared in the body 122.

The driving wheels 123 may be prepared on both sides of the body 122. The driving wheel 123 rotates while the driving wheel 123 is contacted with the transport path 110, and thus, the body 122 may be transported along the transport path 110.

The load/unload unit 125 may include a frame part 126, a slide part 127, a hoist part 128, and a hand part 129.

The frame part 126 is hung under the transport unit 121 to be fixed to the transport unit 121. The frame part 126 has a hollow shape to receive the article 10. Also, a lower portion, both side surfaces or one side surface of the frame part 126 may be opened, and the article 10 may be transported in an up and down direction and a horizontal direction thereof Here, the both side surfaces or the one side surface of the frame part 126 may be substantially perpendicular to the driving direction of the vehicles 120.

The slide part 127 may be prepared on an inner upper surface of the frame part 126, and may be transported in the horizontal direction through the opened side surface of the frame part 126. For example, the slide part 127 may include a guide rail and a transport block.

The hoist part 128 may be fixed on a lower surface of the slide part 127, and may be transported in the horizontal direction by the slide part 127.

The hoist part 128 may fix the hand part 129 and may rise and fall the hand part 129. The hoist part 128 may wrap and unwrap a belt to rise and fall the belt.

The hand part 129 is fixed to an end portion of the belt, and fixes the article 10.

When the hoist part 128 rises and falls the belt, the article 10 fixed to the hand part 129 may rise and fall with respect to the frame part 126.

Also, the article 10 may be transported in the horizontal direction with respect to the frame part 126 by horizontal transportation of the slide part 127.

Although not shown in figures, an additional rotation unit (not shown) may be prepared on the frame part 126, and may rotate the slide part 127, the hoist part 128, and the hand part 129.

The sensors 130 may be prepared on each of the vehicles 120, and may sense operation information related to transport operation and load/unload operation of the vehicles 120.

For example, the operation information may include information of the transport operation for transporting the articles 10 along the transport path 110 by the vehicles 120, information of the load/unload operation for loading and unloading the articles 10 while the vehicles 120 are stopped on the transport path 110, etc.

For example, the operation information may include operation information of motors configured to drive the transport unit 121 and the load/unload unit 125, which are prepared on the vehicles 120, and digital input/output information of a control signal configured to control the motors, etc.

For example, the operation information, may be at least one of a time information, a distance information, a distribution information, and a control sequence information with respect to a unit operation of the vehicles 120.

The time information is information of time for performing the unit operation, and the distance information is information of transport distance of the vehicles 120 or parts of the vehicles 120 for the unit operation. The distribution information is information of distribution degree of values acquired from the vehicles 120 with respect to same unit operation. The control sequence information is information of sequence of control signals provided to the vehicles 120 to perform the unit operation.

As shown in FIG. 1, the position checking unit 140 may include a position display part 141 and a recognizing part 142.

The position display part 141 is prepared on the transport path 110. The position display part 141 may be disposed on a predetermined position of the transport path 110 such as the branched and joined path, the curved path, the inclined path, load/unload position, etc.

Examples of the position display part 141 may include a tag, a bar code, a quick response (QR) code, a reflection plate, etc.

The recognizing part 142 is prepared on the vehicles 120, and recognizes the position display part 141. Examples of the recognizing part 142 may include a tag recognizing sensor, a bar code reader, a quick response (QR) code reader, a photosensor, etc.

Therefore, the position of the vehicles 120 on the transport path 110 may be checked using the position display part 141 and the recognizing part 142.

Alternatively, as shown in FIG. 2, the position checking unit 140 may include a global positioning system (GPS) receiver 143. The GPS receiver 143 may be prepared on the vehicles 120. The GPS receiver 143 receives a GPS signal from a satellite, and may check the position of the vehicles 120 on the transport path 110.

The vehicle inspection device 150 is configured to inspect symptom of abnormality in the vehicles 120, and may include a storing part 152, a diagnosing part 154, and an analyzing part 156.

The storing part 152 may store the operation information in response to the transport operation and the load/unload operation of the vehicles 120. The storing part 152 receives the operation information sensed by the sensors 130 and stores the received operation information.

Also, the storing part 152 may store the position information of each of the vehicles 120, which is acquired by the position checking unit 140, together with the operation information of the vehicles 120 on each of the positions.

For example, the storing part 152 may store the operation information in real time.

In another exemplary embodiment of the present invention, the storing part 152 may store the operation information in a constant period.

Meanwhile, the storing part 152 may store a reference operation information of the vehicles 120 in advance.

For example, the reference operation information may include operation information of normally operating vehicles 120.

In another exemplary embodiment of the present invention, the reference operation information may include operation information of the normally operating vehicles 120, operation information of abnormally operating vehicles 120, and operation information of operating vehicles 120 before the abnormality.

The reference operation information may only include the operation information. However, the reference operation information may also include the position information of each of the vehicles 120 and the operation information of the vehicles 120 at each of the positions.

The diagnosing part 154 may receive the operation information from the storing part 152.

For example, the diagnosing part 154 may receive the operation information of the vehicles 120 from the storing part 152 based on the position of the vehicles 120 on the transport path 110.

In another exemplary embodiment of the present invention, the diagnosing part 154 may receive the operation information from the storing part 152 by each of the vehicles 120.

In still another exemplary embodiment of the present invention, the diagnosing part 154 may receive the position information of each of the vehicles 120 and the operation information of the vehicles 120 at each of the positions from the storing part 152.

The diagnosing part 154 may compare the operation information of the vehicles 120 with the reference operation information, and may diagnose the symptom of the abnormality in the vehicles 120.

Alternatively, the diagnosing part 154 may compare the position information of each of the vehicles 120 and the operation information of the vehicles 120 at each of the positions with the reference operation information, and may diagnose the symptom of the abnormality in the vehicles 120.

When the reference operation information is the operation information of the normally operating vehicles 120 and the operation information is equal to the reference operation information, the diagnosing part 154 may diagnose the vehicles 120 as the normally operating vehicles 120. When the reference operation information is the operation information of the normally operating vehicles 120 and the operation information is not equal to the reference operation information, the diagnosing part 154 may diagnose the vehicles 120 as the vehicles 120 having the symptom of the abnormality.

In another exemplary embodiment of the present invention, when the reference operation information includes all of the operation information of the normally operating vehicles 120, the operation information of the abnormally operating vehicles 120, and the operation information of the vehicles 120 having the symptom of the abnormality and the operation information is equal to the reference operation information, the diagnosing part 154 may diagnose the vehicles 120 as the normally operating vehicles 120. When the reference operation information includes all of the operation information of the normally operating vehicles 120, the operation information of the abnormally operating vehicles 120, and the operation information of the vehicles 120 having the symptom of the abnormality and the operation information is equal to the operation information before the occurrence of the abnormality, the diagnosing part 154 may diagnose the vehicles 120 as the vehicles 120 having the symptom of the abnormality.

Meanwhile, the diagnosing part 154 may diagnose the symptom of the abnormality in the vehicles 120 in real time. That is, when the diagnosing part 154 receives the operation information of the vehicles 120 from the storing part 152, the diagnosing part 154 may immediately diagnose the symptom of the abnormality of the vehicles 120.

Alternatively, the diagnosing part 154 may diagnose the symptom of the abnormality in the vehicles 120 in a constant period.

The storing of the operation information by the storing part 152 and the diagnosing of the symptom of the abnormality by the diagnosing part 154 may be performed in real time or may be performed in a constant period.

Since the diagnosing part 154 may diagnose the symptom of the abnormality in the vehicles 120 in advance, the vehicles 120 having the symptom of the abnormality may be preventively maintained, and the occurrence of the abnormality in the vehicles 120 may be decreased. Stoppage of the article transfer system 100 caused by the abnormality of the vehicles 120 is decreased, and thus, efficiency of the article transfer system 100 may be improved.

As shown in FIG. 1, when the storing part 152 is prepared to be separated from the vehicles 120, each of the vehicles 120 may exchange the operation information and the reference operation information with the storing part 152 through wireless communication. Examples of the wireless communication may include Wi-Fi communication, Bluetooth communication, near field communication (NFC), Zigbee communication, etc.

As shown in FIG. 3, when the storing part 152 is prepared on each of the vehicles 120, each of the storing part 152 may exchange the operation information and the reference operation information with the diagnosing part 154 through the wireless communication.

When the diagnosing part 154 diagnoses the vehicles 120 to have the symptom of the abnormality, that is, when the vehicles 120 has the symptom of the abnormality, or when the transfer path 110 has the symptom of the abnormality, the analyzing part 156 may analyze history information of the occurrence of the abnormality in the vehicles 120 at the position of the vehicles 120.

When the symptom of the abnormality is repeatedly generated in a specified vehicle among the vehicles 120, the analyzing part 156 determines that the specified vehicle has the cause of the occurrence of the abnormality.

When the symptom of the abnormality is repeatedly generated in a plurality of vehicles 120 at a specified position of the transfer path 110, the analyzing part 156 determines that the occurrence of the abnormality is caused by external environment including the transfer path 110.

Therefore, the cause of the occurrence of the abnormality in the vehicles 120 may be easily determined whether the occurrence of the abnormality is from the vehicles 120 itself or from the external environment including the transfer path 110.

Since the cause of the occurrence of the abnormality in the vehicles 120 may be exactly checked by the analyzing part 156, the cause of the occurrence of the abnormality may be rapidly and exactly resolved.

According to the present invention, the vehicle inspection device analyzes the information of the operation of the vehicles, and may diagnose the symptom of abnormality in the vehicles. Therefore, the vehicles having the symptom of the abnormality are preventively maintained, and the abnormality of the vehicles may be decreased. Since the stoppage of the vehicle transport system caused by the abnormality of the vehicles is decreased, the efficiency of the vehicle transport system may be improved.

Also, in the vehicle inspection device, when the diagnosing part diagnoses the symptom of the abnormality, the position of the vehicles and the hysteresis of the abnormality in the vehicles are analyzed, and the cause of the abnormality in the vehicles may be analyzed whether the abnormality is caused by the vehicle itself or caused by the external environment out of the vehicles. Therefore, the cause of the abnormality may be rapidly diagnosed and resolved.

Although the example embodiments of the present invention have been described with reference to the specific embodiments, they are not limited thereto. Therefore, it will be readily understood by those skilled in the art that various modifications and changes can be made thereto without departing from the spirit and scope of the appended claims.

What is claimed is:

1. A vehicle inspection device comprising:
a storing part configured to store operation information in response to operations of vehicles to transport and load/unload an article along a transfer path; and
a diagnosing part configured to compare the operation information stored in the storing part with a reference operation information of a vehicle to diagnose symptom of abnormality in the vehicles.

2. The vehicle inspection device of claim 1, wherein the diagnosing part receives the operation information from the storing part based on position of the vehicles in the transfer path.

3. The vehicle inspection device of claim 1, wherein the diagnosing part receives the operation information from the storing part by each of the vehicles.

4. The vehicle inspection device of claim 1, further comprising an analyzing part configured to analyze cause of the abnormality in the vehicles using position of the vehicles and history information of occurrence of the abnormality in the vehicles, the analyzing part analyzing whether the cause of the abnormality in the vehicles is the vehicles itself or is from external environment including the transfer path, when the diagnosing part diagnoses the symptom of the abnormality.

5. The vehicle inspection device of claim 1, wherein the storing part stores the operation information in real time.

6. The vehicle inspection device of claim 1, wherein the storing part stores the operation information in a constant period.

7. The vehicle inspection device of claim 1, wherein the operation information is acquired by sensors prepared on the vehicles, and the operation information comprises information of transport operation and information of load/unload operation of the vehicles.

8. The vehicle inspection device of claim 1, wherein the operation information is acquired by sensors prepared on the vehicles, and the operation information comprises at least one of operation information and digital input/output information of motors prepared on the vehicles.

9. The vehicle inspection device of claim 1, wherein the operation information is acquired by sensors prepared on the vehicles, and the operation information comprises at least one of time information, distance information, distribution information, and control sequence information of unit operation of the vehicles.

10. The vehicle inspection device of claim 1, wherein the storing part is prepared on each of the vehicles, and the storing part exchanges the information with the diagnosing part through wireless communication.

11. The vehicle inspection device of claim 1, wherein the storing part is prepared to be separated from the vehicles, and the vehicles exchanges the information with the storing part through wireless communication.

12. A vehicle inspection device comprising:
a storing part configured to store position information of each of a plurality of vehicles and operation information of the vehicles at each position with respect to the vehicles configured to transport and load/unload an article along a transport path; and
a diagnosing part configured to compare the position information of the vehicles, which is stored in the storing part, with a previously stored reference operation information, and to diagnose symptom of abnormality of the vehicles.

13. The vehicle inspection device of claim 12, further comprising an analyzing part configured to analyze position of the vehicles and history information of occurrence of the abnormality in the vehicles to determine whether cause of the abnormality in the vehicles is the vehicles itself or is from external environment including the transfer path, when the diagnosing part diagnoses the symptom of the abnormality.

14. An article transfer system comprising:
a transfer path;
a plurality of vehicles configured to transfer and load/unload an article along the transfer path;
a plurality of sensors prepared on each of the vehicles and configured to sense operation information of the vehicles;
a storing part configured to store operation information of the vehicles, which is transmitted from the sensors; and
a diagnosing part configured to compare the operation information stored in the storing part with a reference operation information of a vehicle, which is previously stored, to diagnose symptom of abnormality of the vehicles.

15. The article transfer system of claim 14, wherein the diagnosing part receives the operation information from the storing part based on position of the transfer path.

16. The article transfer system of claim 14, wherein the diagnosing part receives the operation information from the storing part by each of the vehicles.

17. The article transfer system of claim 14, further comprising an analyzing part configured to analyze whether cause of the abnormality in the vehicles is the vehicles itself or is from external environment including the transfer path using position of the vehicles and history information of occurrence of the abnormality in the vehicles, when the diagnosing part diagnoses the symptom of the abnormality.

18. The article transfer system of claim 14, further comprising a position checking unit including:
a position display part prepared on the transfer path to check position of the vehicles on the transfer path; and
a recognizing part prepared on the vehicles to recognize the position display part.

19. The article transfer system of claim 14, further comprising a position checking unit including a global position system (GPS) receiver prepared on each of the vehicles to check position of the vehicles on the transfer path.

20. The article transfer system of claim 14, wherein the article comprises a storage container configured to store a good.
